(19) United States
(12) Patent Application Publication
(10) Pub. No.: US 2011/0001207 A1
(43) Pub. Date: Jan. 6, 2011

(54) SOLID STATE IMAGE SENSOR AND MANUFACTURING METHOD THEREOF

(76) Inventors: Masayuki TAKASE, Osaka (JP); Hirohisa Ohtsuki, Hyogo (JP); Hiroyuki Doi, Kyoto (JP); Motonari Katsuno, Kyoto (JP)

Correspondence Address: MCDERMOTT WILL & EMERY LLP, 600 13TH STREET, NW, WASHINGTON, DC, 20005-3096, US

(21) Appl. No.: 12/820,655

(22) Filed: Jun. 22, 2010

(30) Foreign Application Priority Data
Jul. 3, 2009 (JP) 2009-158741

(51) Int. Cl. H01L 31/0232; H01L 31/18

(52) U.S. Cl. 257/432; 438/70; 257/E31.127

(57) ABSTRACT

A solid state image sensor includes: a first pixel and a second pixel, each including a light receiving portion; a first color filter formed in an upper part of the first pixel on a first main surface side of a semiconductor substrate; a second color filter formed in an upper part of the second pixel on the first main surface side of the semiconductor substrate; a metal interconnect layer formed on a second main surface side of the semiconductor substrate; and a substrate contact connected to the second main surface of the semiconductor substrate, and provided between the metal interconnect layer and the second main surface. The first color filter mainly transmits first light therethrough, and the second color filter mainly transmits second light therethrough. The second light has a shorter wavelength than that of the first light. The substrate contact is not provided in the first pixel.

### CROSS-REFERENCE TO RELATED APPLICATION

This application claims priority from Japanese Patent Application No. 2009-158741 filed on Jul. 3, 2009, the disclosure of which application is hereby incorporated by reference into this application in its entirety for all purposes.

### BACKGROUND

A technique described in the present disclosure relates to back-illuminated metal oxide semiconductor (MOS) solid state image sensors having a sensor portion. MOS solid state image sensors, which are used as imaging devices such as digital still cameras and mobile phones with cameras, have a sensor portion in which a plurality of pixel cells are arranged in a two-dimensional pattern. The structure of this sensor portion will be described below with reference to FIGS. 9A-9B and FIG. 10.

FIG. 9A is a diagram showing a pixel array 201 and a peripheral circuit thereof in a conventional MOS solid state image sensor 200. FIG. 9B is a circuit diagram showing the circuit configuration of a pixel cell 202 of the pixel array 201. FIG. 10 is a cross-sectional view of a pixel portion of the conventional solid state image sensor 200 (see, e.g., Japanese Published Patent Application No. 2003-273343).

As shown in FIGS. 9A-9B and FIG. 10, the pixel array 201 of the MOS solid state image sensor 200 is formed by arranging pixel cells 202 in an array of rows and columns. The pixel cells 202 include several kinds of color filters 204, each transmitting only light 215 of a specific wavelength range therethrough, and photodiodes 207 formed under each color filter 204 (FIG. 9A).

As shown in FIG. 9A, a circuit block of the solid state image sensor 200 includes the pixel array 201, a vertical scanning circuit 205 for horizontally selecting the pixel cells 202, signal lines 203 for reading data from the pixel cells 202, and a read circuit 206 for reading signals from the pixel cells 202.

As shown in FIG. 9B, each pixel cell 202 has a color filter (not shown), a photodiode 207, and four transistors. Specifically, the four transistors are a transfer transistor 208, an amplifying transistor 209, a reset transistor 210, and a select transistor 211, which are provided as components of a circuit shown in FIG. 9B. As shown in FIG. 9A, substrate contacts 212 are positioned between adjoining ones of the pixel cells 202 in order to stably operate the four transistors at a high speed to stabilize a well potential.

An operation of this circuit configuration will be described briefly below.

As shown in FIG. 9B, the photodiode 207 is an element portion for converting light, received through the color filter, to charges corresponding to the intensity of the received light, and accumulating the charges therein. One end of the photodiode 207 is connected to the source of the transfer transistor 208. The drain of the transfer transistor 208 is connected to the source of the reset transistor 210 and the gate of the amplifying transistor 209. The drain of the reset transistor 210 and the drain of the amplifying transistor 209 are connected to a power supply line having a potential of, e.g., 3.3 V, and the source of the amplifying transistor 209 is connected via the select transistor 211 to the signal line 203 for reading data. With this configuration, external light is received by the pixel array 201 and converted to an electrical signal, which is amplified and transferred as image data.

As shown in FIG. 10, in a pixel portion 220, a P-well region 222 is provided in the upper part of an N-type silicon substrate 221, and a photodiode 207 is provided in the P-well region 222. An upper insulating layer 223 is provided on the surface of the N-type silicon substrate 221, which is opposite to the surface at which the photodiode 207 is formed. A polysilicon transfer electrode (not shown), and an interconnect layer 224 located above the polysilicon transfer electrode are provided in the upper insulating layer 223. Metal interconnects such as copper are formed in the interconnect layer 224. An on-chip color filter 204 and an on-chip microlens 225 are provided on the surface of the N-type silicon substrate 221 which is opposite to the surface over which the interconnect layer 224 is provided. That is, the back surface having no interconnect layer 224 formed thereon serves as the light receiving surface of the photodiode 207. Thus, the aperture ratio is large, and light is neither reflected nor scattered by the interconnect layer 224, whereby photoelectric sensitivity can be increased.

### SUMMARY

However, the above conventional technique has a problem that shading in output signals increases as the number of pixels in the solid state image sensor increases. In particular, as the number of pixels increases, shading increases in output signals from those photodiodes which are positioned under color filters for transmitting therethrough only long wavelength visible light, e.g., red light.

According to a solid state image sensor of an embodiment of the present invention, substrate contacts are appropriately positioned according to the colors of color filters, whereby generation of shading can be reduced.

A solid state image sensor according to an example of the present disclosure includes: a semiconductor substrate having a first main surface and a second main surface which face each other; a first pixel and a second pixel, each including a light receiving portion formed in the semiconductor substrate and configured to perform photoelectric conversion; a first color filter formed in an upper part of the first pixel on the first main surface side of the semiconductor substrate; a second color filter formed in an upper part of the second pixel on the first main surface side of the semiconductor substrate; a metal interconnect layer formed on the second main surface side of the semiconductor substrate; and a substrate contact connected to the second main surface of the semiconductor substrate, and provided between the metal interconnect layer and the second main surface. The first color filter mainly transmits first light therethrough, the second color filter mainly transmits second light therethrough, the second light has a shorter wavelength than that of the first light, and the substrate contact is not provided in the first pixel.

By providing the substrate contact, the shape of a depletion layer around a lower part of the light receiving portion located near the substrate contact (in a portion near the second main surface) varies from the shape in the case where no substrate contact is provided. Since the substrate contact is not provided in the first pixel that receives the first light having a long wavelength, a variation in sensitivity among multiple ones of the first pixel can be reduced. Thus, the above configuration can effectively reduce generation of shading, whereby sensitivity to long wavelength visible light can be made more uniform among the pixels.

The solid state image sensor may further include: a third pixel including the light receiving portion formed in the semiconductor substrate; and a third color filter formed in an upper part of the third pixel on the first main surface side of the semiconductor substrate, wherein the third color filter may mainly transmit third light therethrough, the third light may have a shorter wavelength than that of the second light, and the substrate contact may be provided at least in the third pixel.

Since light having a short wavelength is absorbed at a shallow depth in the semiconductor substrate, sensitivity changes relatively slightly by the presence of the substrate contact. Thus, the above configuration can effectively reduce generation of shading.

The second pixel and the third pixel may be positioned so as to adjoin each other, and the substrate contact may be formed over a boundary between the second pixel and the third pixel.

With this configuration, the substrate contact can be shared by the pixels, and the number of substrate contacts can be reduced. Thus, the pixels can be miniaturized to further reduce the cost of the solid state image sensor and to increase the integration level thereof.

The substrate contact may be formed between the light receiving portion of the second pixel and the light receiving portion of the third pixel as viewed in plan.

This configuration enables the substrate contact to be located farthest from the first pixel for detecting long wavelength light. Thus, the sensitivity to long wavelength light can be made more uniform among a plurality of pixels.

The substrate contact may be formed at a position closer to the light receiving portion of the third pixel than to the light receiving portion of the second pixel as viewed in plan.

With this configuration, the substrate contact is located closer to the third pixel for detecting light of the shortest wavelength range. This can reduce even a slight variation in sensitivity among multiple ones of the second pixel, whereby the sensitivity can be made more uniform among the pixels.

The first light may be red light, the second light may be green light, the third light may be blue light, and multiple ones of the first pixel, the second pixel, and the third pixel may be provided, and may be arranged in a Bayer pattern.

This configuration can reduce a variation in sensitivity to red (R) light, green (G) light, and blue (B) light, whereby generation of shading can further be reduced. Thus, the sensitivity can be made more uniform among the pixels.

The solid state image sensor may further include: a transfer transistor provided on the first main surface of the semiconductor substrate, and configured to transfer a signal accumulated in the first pixel, the second pixel, or the third pixel; and a reset transistor provided on the first main surface of the semiconductor substrate, wherein the reset transistor may be positioned between the transfer transistor and the substrate contact as viewed in plan.

This configuration enables the substrate contact to be separated from the transfer transistor, whereby the sensitivity of the light receiving portion can be made uniform among the pixels of the same color.

A method for manufacturing a solid state image sensor according to an example of the present invention includes the steps of: forming a light receiving portion, which is configured to convert light incident from a first main surface side of a semiconductor substrate to a signal, in each of a first pixel and a second pixel in the semiconductor substrate; forming a substrate contact connected to a second main surface of the semiconductor substrate, and a metal interconnect layer, on the second main surface side of the semiconductor substrate; forming a first color filter in an upper part of the first pixel on the first main surface side of the semiconductor substrate; and forming a second color filter in an upper part of the second pixel on the first main surface side of the semiconductor substrate. The first color filter mainly transmits first light therethrough, the second color filter mainly transmits second light therethrough, the second light has a shorter wavelength than that of the first light, and the substrate contact is not formed in the first pixel.

According to this method, the substrate contact is not provided in the first pixel that receives long wavelength light. This can reduce the influence of deformation of a depletion layer caused by the substrate contact, in the first pixel. Thus, a variation in sensitivity among multiple ones of the first pixel can be reduced, whereby generation of shading can be reduced, and sensitivity to long wavelength light can be made more uniform among the pixels.

The light receiving portion may be formed also in a third pixel in the step of forming the light receiving portion, and the method may further include the step of: forming, in an upper part of the third pixel, a third color filter configured to mainly transfer therethrough third light having a shorter wavelength than that of the second light. The substrate contact may be formed at least in the third pixel in the step of forming the substrate contact.

Since the third pixel receives the third light having a short wavelength, sensitivity is less likely to change due to the presence of the substrate contact. Thus, the above method can reduce generation of shading, whereby sensitivity to long wavelength light can be made uniform among multiple ones of the first pixel.

According to the solid state image sensor and the manufacturing method according to the example of the present invention, the substrate contact is not provided in the first pixel that detects light having a long wavelength, but in the pixel that detects light having a shorter wavelength. Thus, generation of shading can be reduced, whereby the sensitivity to long wavelength light can be made uniform among the pixels.

### BRIEF DESCRIPTION OF THE DRAWINGS

FIG. 1A is a plan view schematically showing the configuration of a pixel array portion in a solid state image sensor according to an embodiment of the present invention, and FIG. 1B is a cross-sectional view of the solid state image sensor taken along line 1B-1B in FIG. 1A.

FIG. 2 is a graph showing the relation between the light wavelength and the absorption coefficient of a silicon substrate, and the light penetration depth in the silicon substrate.

FIG. 3A is a plan view of a pixel array portion in a solid state image sensor, and FIG. 3B is a cross-sectional view of the solid state image sensor taken along line 3B-3B in FIG. 3A.

FIG. 4 is a schematic cross-sectional view of the solid state image sensor of the embodiment of the present invention, taken along line 4A-4A in FIG. 1A.

FIG. 5 is a timing chart illustrating an electrical operation of the solid state image sensor of the embodiment of the present invention.

FIG. 6 is a flowchart illustrating a manufacturing method of the solid state image sensor of the embodiment of the present invention.

FIG. 7 is a plan view schematically showing the configuration of a pixel array portion according to a modification of the solid state image sensor shown in FIGS. 1A-1B.

FIG. 8 is a diagram schematically showing the circuit configuration of a circuit block of a solid state image sensor according to a modification of the embodiment of the present invention.

FIG. 9A is a diagram showing a pixel array and a peripheral circuit thereof in a conventional MOS solid state image sensor, and FIG. 9B is a circuit diagram showing the circuit configuration of a pixel cell of the pixel array.

FIG. 10 is a cross-sectional view of a pixel portion of the conventional solid state image sensor.

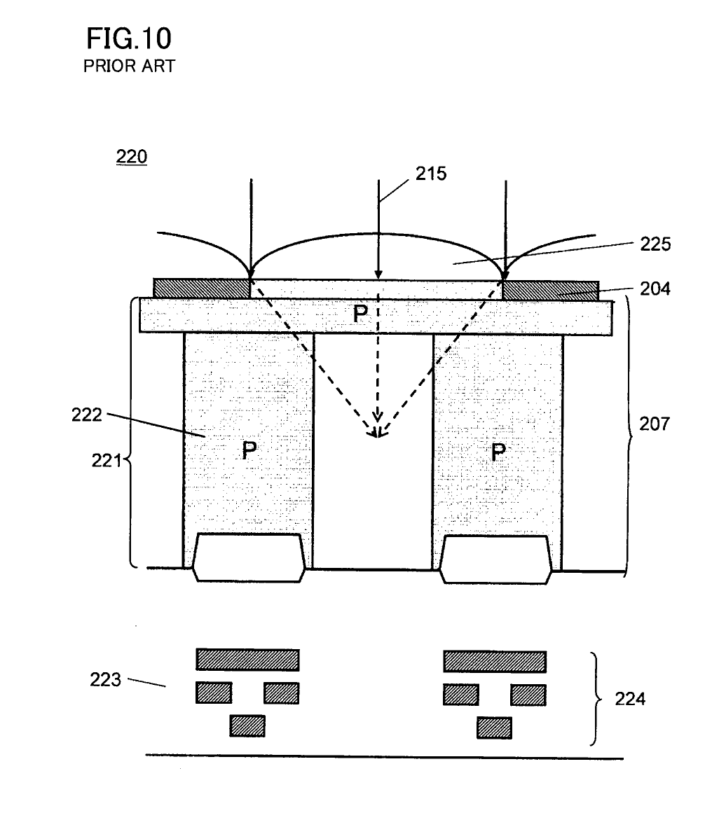

### DETAILED DESCRIPTION

An embodiment of the present invention will be described below with reference to the accompanying drawings. Note that like reference characters represent like components throughout the figures. In order to facilitate understanding, components are shown schematically in the figures.

### Embodiment

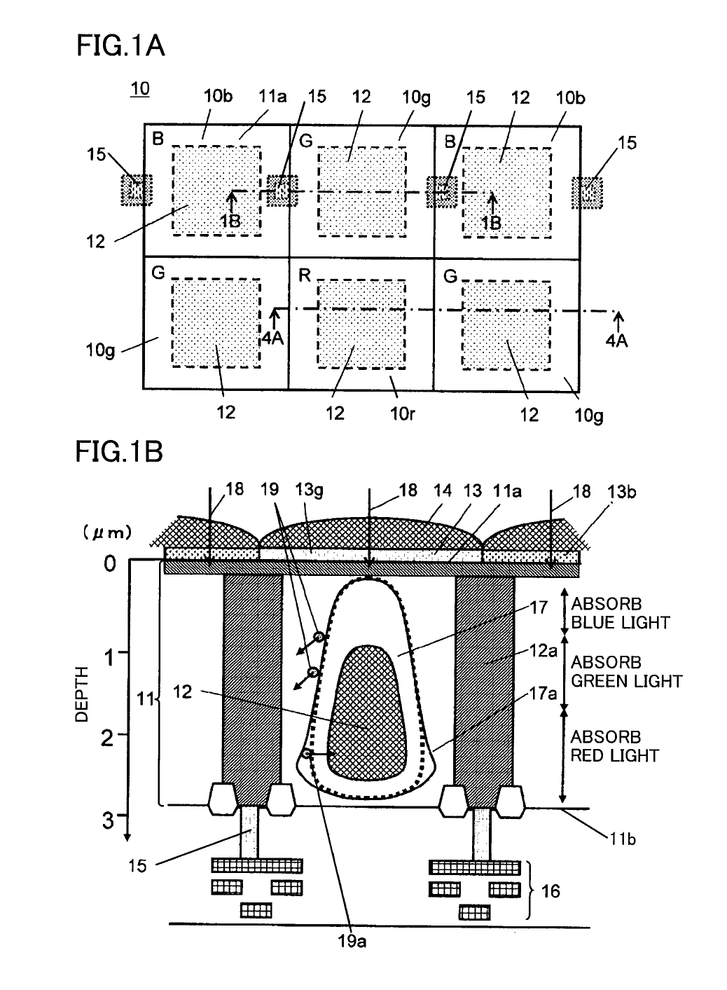

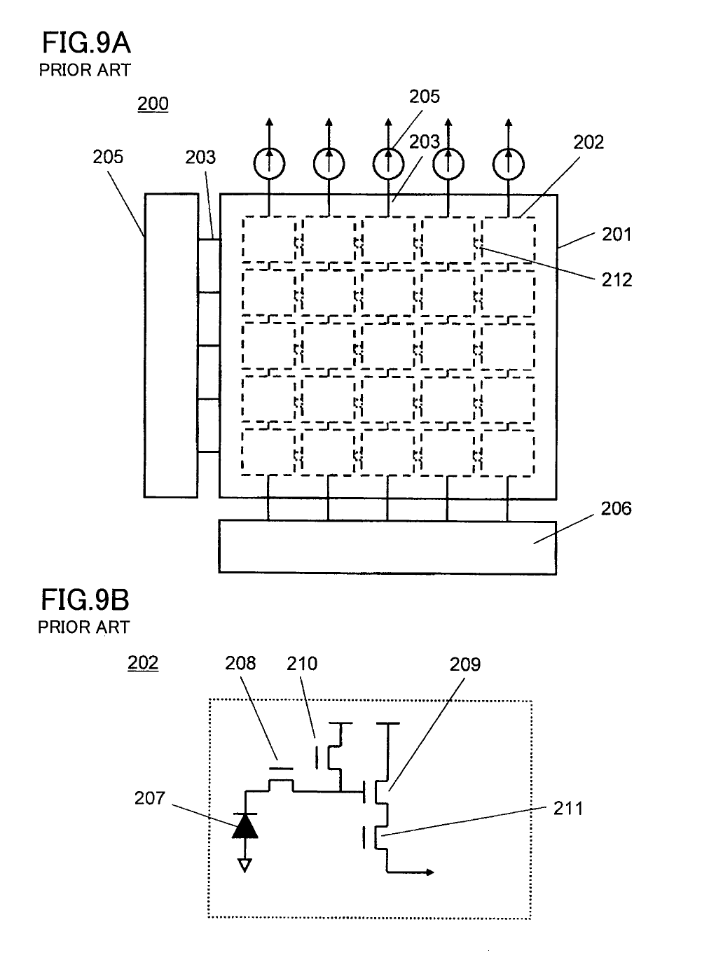

FIG. 1A is a plan view schematically showing the configuration of a pixel array portion 10 in a solid state image sensor according to an embodiment of the present invention. FIG. 1B is a cross-sectional view of the solid state image sensor taken along line 1B-1B in FIG. 1A. In FIG. 1B, a first main surface 11a of a semiconductor substrate 11 is shown to face upward, and a second surface 11b opposite to the first main surface 11a is shown to face downward. Note that the configuration other than the pixel array portion 10 of the solid state image sensor of the present embodiment is similar to that of the solid state image sensor shown in FIGS. 9A-9B.

That is, the solid state image sensor of the present embodiment includes the pixel array portion 10, a vertical scanning circuit for horizontally selecting pixel cells, signal lines for reading data from the pixel cells, and a read circuit for reading signals from the pixel cells.

As shown in FIG. 1A, the pixel array portion 10 include, as a basic configuration, first pixels 10r, second pixels 10g, and third pixels 10b as pixel cells. The first pixels 10r, the second pixels 10g, and the third pixels 10b detect red light, green light, and blue light, respectively. As shown in FIG. 1B, each of the first pixels 10r, the second pixels 10g, and the third pixels 10b has a photodiode (a light receiving portion) 12, a color filter 13, a microlens 14, and a circuit portion. The photodiode 12 is formed in the semiconductor substrate 11. The circuit portion is, for example, a circuit including a transfer transistor 208, an amplifying transistor 209, a reset transistor 210, and a select transistor 211 as shown in FIG. 9B. The photodiode 12 is formed in, e.g., a p-type semiconductor substrate 11 (or a p-type well), and is formed by an N-type layer, and a P-type region forming a PN junction with the N-type layer.

As shown in FIGS. 1A-1B, the solid state image sensor of the present embodiment includes the first pixels 10r, the second pixels 10g, the third pixels 10b, first color filters (not shown), second color filters 13g, and third color filters 13b. The first pixels 10r, the second pixels 10g, and the third pixels 10b include the photodiodes 12 formed in the semiconductor substrate 11. Each of the first color filters is formed in the upper part of a corresponding one of the first pixels 10r on the first main surface 11a side of the semiconductor substrate 11. Each of the second color filters 13g is formed in the upper part of a corresponding one of the second pixels 10g on the first main surface 11a side of the semiconductor substrate 11 (above the first main surface 11a). Each of the third color filters 13b is formed in the upper part of a corresponding one of the third pixels 10b on the first main surface 11a side of the semiconductor substrate 11 (above the first main surface 11a). The solid state image sensor further includes the microlenses 14 provided on the color filters of the pixels.

The solid state image sensor further includes a stacked interconnect layer (a metal interconnect layer) 16 and substrate contacts 15. The stacked interconnect layer 16 is formed on the second main surface 11b side of the semiconductor substrate 11 (under the second main surface 11b), which is opposite to the first main surface 11a. The substrate contacts 15 are conductors connected to the second main surface 11b of the semiconductor substrate 11 and diffusion layers 12a formed in the semiconductor substrate 11. Note that if the semiconductor substrate 11 is a p-type semiconductor substrate, the diffusion layers 12a contain a higher concentration of p-type impurities than the semiconductor substrate 11 does.

As described below, the substrate contacts 15 are provided between adjoining ones of the photodiodes 12 in order to stabilize a well potential. A reference voltage of, e.g., 0 V is applied to the substrate contacts 15.

The first color filters mainly transmit first light (red light) therethrough, the second color filters 13g mainly transmit second light (green light) therethrough, and the third color filters 13b mainly transmit third light (blue light) therethrough. The wavelength of the second light is shorter than that of the first light, and the wavelength of the third light is shorter than that of the second light. In the solid-state image sensor of the present embodiment, no substrate contact 15 is provided in the first pixels 10r, and most of the substrate contacts 15 are positioned in the third pixels 10b rather than in the second pixels 10g.

This configuration can prevent or reduce deformation of depletion layers 17 due to the presence of the substrate contacts 15 as described below, and can reduce a variation in sensitivity to long wavelength visible light among the plurality of first pixels 10r. Thus, generation of shading can be reduced, and the sensitivity to long wavelength visible light can be made more uniform among the first pixels 10r. Note that it is only necessary that no substrate contact 15 be provided in the first pixels 10r, and the substrate contacts 15 may be positioned both in the third pixels 10b and the second pixels 10g.

The solid state image sensor configured as described above will be described in more detail below.

In the solid state image sensor of FIG. 1B, light 18 is collected by the microlens 14 onto, e.g., the photodiode 12 in the second pixel 10g. Since the light 18 passes through the second color filer 13g, the light incident on the photodiode 12 mainly has a wavelength of 490 nm to 575 nm. This light is photoelectrically converted to electrons 19 as carriers at a depth of 0.5 μm to 1.5 μm in the semiconductor substrate 11 that is made of, e.g., a silicon material. Although the substrate contacts 15 are positioned near the photodiode 12, the photoelectric conversion is performed at a depth of about 0.5 μm to 1.5 μm, where a divide 17a of a depletion layer 17 hardly changes due to the presence of the substrate contacts 15. Thus, the second pixel 10g is less susceptible to a change in sensitivity due to the presence of the substrate contacts 15.

As used herein, the term “divide of the depletion layer” refers to a potential barrier (a high potential region) of a P-type (a second conductivity type) silicon layer, which separates the semiconductor substrate 11 from an N-type (a first conductivity type) region of the photodiode 12.

For example, if no second color filter 13g is provided in the upper part of the second pixel 10g, and red light having a wavelength of 575 nm to 700 nm is incident on the photodiode 12, photoelectric conversion is performed at a depth of 1.5 μm to 3.0 μm, where the divide 17a of the depletion layer 17 changes. In this case, electrons 19a generated by the photoelectric conversion travel away from the substrate contacts 15 due to the change of the divide 17a of the depletion layer 17. Thus, the red light reaching a region near the photodiode 12 contributes to an increase in sensitivity as an electrical signal, whereby the sensitivity is varied.

As shown in FIGS. 1A-1B, the substrate contacts 15 are positioned closer to the photodiodes 12 of the third pixels 10b adjoining the second pixel 10g, than to the photodiode 12 of the second pixel 10g.

This can further reduce a change in sensitivity caused by providing the substrate contacts 15. As shown in FIG. 1B, each substrate contact 15 is positioned so as to extend over the line connecting the centers of two adjoining photodiodes 12 with the diffusion layer 12a interposed therebetween. This can further reduce a variation in sensitivity according to the incidence direction of light 18, while increasing the flexibility of layout.

Note that, in FIG. 1A, light is incident on the photodiode 12 of the first pixel 10r from the first main surface 11a located opposite to the second main surface 11b. Thus, this incident light passes through the first color filter 13r that transmits only red light therethrough. Accordingly, the light incident on this photodiode 12 mainly has a wavelength of 575 nm to 700 nm, and is photoelectrically converted at a great depth (about 1.5 μm to 3.0 μm) in the semiconductor substrate 11. Since no substrate contact 15 is provided near this photodiode 12, the sensitivity does not vary depending on the incidence direction of light.

Similarly, of the lower three pixels 10g, 10r, and 10g of FIG. 1A, light, which is incident on the photodiodes 12 of the second pixels 10g adjoining each other with the first pixel 10r interposed therebetween, passes through the second color filters 13g that transmit only green light therethrough. Thus, the light incident on these photodiodes 12 mainly has a wavelength of 490 nm to 575 nm, and is photoelectrically converted at a depth of about 0.5 μm to 1.5 μm in the semiconductor substrate 11. Since no substrate contact 15 is provided near these photodiodes 12, the sensitivity does not vary depending on the incidence direction of light.

Similarly, of the upper three pixels 10b, 10g, and 10b of FIG. 1A, light, which is incident on the photodiodes 12 of the third pixels 10b adjoining each other with the second pixel 10g interposed therebetween, passes through the third color filters 13b that transmit only blue light therethrough. Thus, the light incident on these photodiodes 12 mainly has a wavelength of 400 nm to 490 nm, and is photoelectrically converted at a shallow depth (about 0.2 μm to 0.5 μm) in the semiconductor substrate 11. Since charges are generated at a shallow depth, the divide 17a of the depletion layer 17 hardly changes even if the substrate contacts 15 are provided near the photodiodes 12. Thus, the sensitivity does not change.

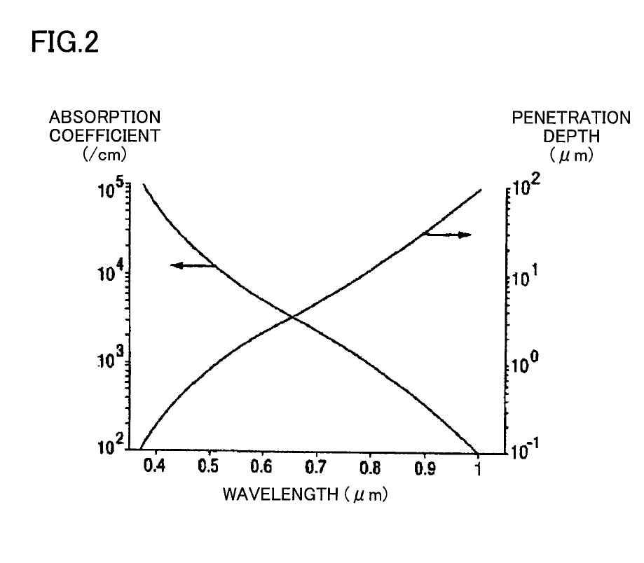

FIG. 2 is a graph showing the relation between the light wavelength and the absorption coefficient of the silicon substrate, and showing the light penetration depth in the silicon substrate. As shown in FIG. 2, in and around the visible light wavelength range, the absorption coefficient decreases and the light penetration depth increases, as the wavelength increases.

It can be seen from FIG. 2 that, as the wavelength increases from blue light toward green and red light, the light reaches a greater depth in the semiconductor substrate 11. Thus, in the solid state image sensor of the present embodiment, a variation in sensitivity among the pixels can be reduced even if the substrate contacts 15 are not provided in the first pixels 10r, but in the second pixels 10g in the regions where the first pixel 10r and the second pixel 10g adjoin each other.

In the case where the substrate contacts 15 are not provided in the first pixels 10r and the second pixels 10g, but in the third pixels 10b, the sensitivity can be made more uniform among the pixels, whereby generation of shading can be effectively reduced.

Alternatively, in the case where the substrate contacts 15 are provided both in the second pixels 10g and the third pixels 10b, not only generation of shading is reduced, but also the substrate potential can be stabilized via the substrate contacts 15. Thus, the sensitivity to long wavelength visible light can be made more uniform among the pixels.

As shown in FIGS. 1A-1B, most of the substrate contact 15 may be positioned in the third pixel 10b. Alternatively, the substrate contact 15 may extend over the boundary between the second pixel 10g and the third pixel 10b.

With this configuration, each substrate contact 15 can be positioned between the pixels and shared by the pixels, whereby the number of substrate contacts 15 can be reduced. Thus, the pixels can be miniaturized, thereby reducing the cost of the solid state image sensor, and increasing the integration level thereof.

As shown in FIG. 1A, the substrate contact 15 may be formed between the photodiode 12 of the second pixel 10g and the photodiode 12 of the third pixel 10b.

With this configuration, the substrate contacts 15 can be positioned farthest from the pixels for detecting long wavelength visible light, e.g., the first pixels 10r, whereby the sensitivity to long wavelength visible light can be made more uniform among the pixels.

As shown in FIG. 1A, the substrate contact 15 may be formed between the photodiode 12 of the second pixel 10g and the photodiode 12 of the third pixel 10b at a position closer to the photodiode 12 of the third pixel 10b.

The substrate contact 15 is formed close to the third pixel 10b for detecting visible light of the shortest wavelength range, even a slight variation in sensitivity among the second pixels 10g can be reduced, whereby the sensitivity can be made more uniform among the pixels.

The first light is mainly the red light, the second light is manly the green light, and the third light is mainly the blue light, and the first pixels 10r, the second pixels 10g, and the third pixels 10b may be arranged in a Bayer pattern.

This configuration can reduce a variation in sensitivity to the red light, the green light, and the blue light, thereby further reducing generation of shading. Thus, the sensitivity can be made more uniform among the pixels.

As described above, in the solid state image sensor of the present embodiment, the substrate contacts 15 are mainly positioned near the photodiodes 12 located under the third color filters 13b of the third pixels 10b. With this configuration, generation of shading can be reduced without varying the sensitivity to any wavelength, while stably maintaining the well potential of the transistors.

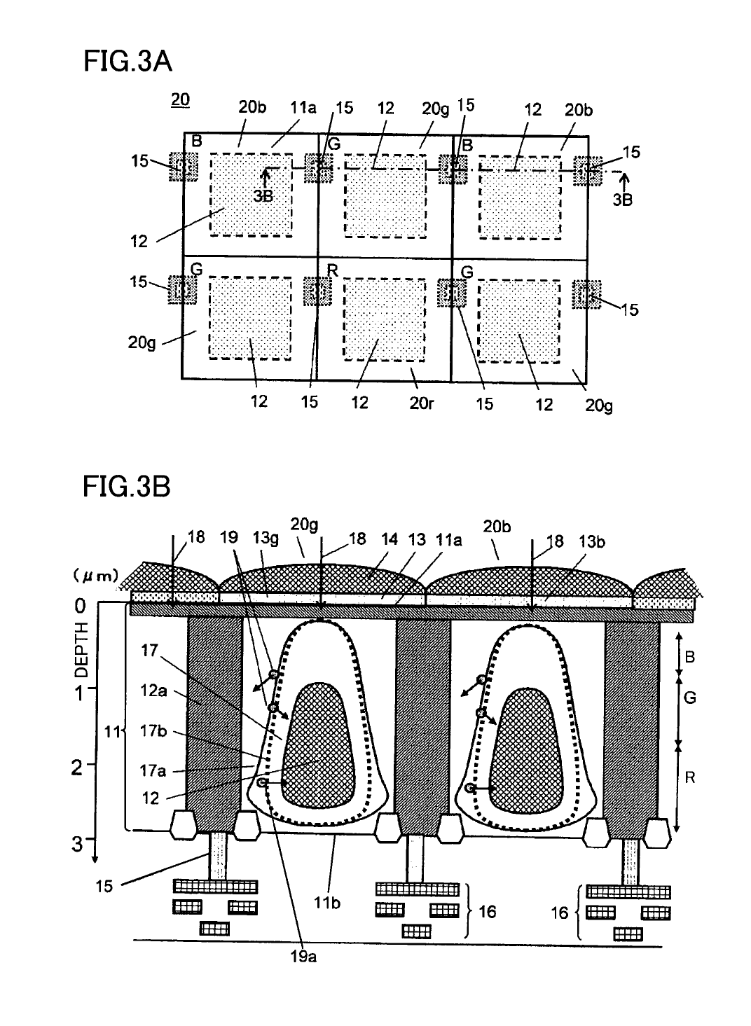

FIGS. 3A-3B are diagrams schematically showing the configuration of a pixel array portion 20 of a solid state image sensor of a first modification in which substrate contacts 15 are positioned between adjoining ones of the pixels. FIG. 3A is a plan view of the pixel array portion 20, and FIG. 3B is a cross-sectional view of the solid state image sensor taken along line 3B-3B in FIG. 3A. In FIG. 3B, a first main surface 11a of a semiconductor substrate 11 is shown to face upward, and a second main surface 11b thereof is shown to face downward. Note that the configuration other than the pixel array portion 20 of the solid state image sensor of FIGS. 3A-3B is similar to the conventional configuration shown in FIGS. 9A-9B.

Unlike in the pixel array portion 10 of FIG. 1A, each substrate contact 15 is positioned on the boundary between adjoining ones of the pixels in the lower three pixels (a second pixel 20g, a first pixel 20r, and a second pixel 20g) of the pixel array portion 20 in FIG. 3A. In FIG. 1A, the substrate contacts 15 are positioned closer to the third pixels 10b than to the second pixel 10g. However, in FIG. 3A, each substrate contact 15 is positioned substantially on the boundary between the second pixel 20g and the third pixel 20b. Note that provided that the photodiodes 12 have a quadrilateral shape, each substrate contact 15 is positioned between an upper corner of the photodiode 12 in the second pixel 20g and an upper corner of the photodiode 12 in the third pixel 20b as viewed in plan.

In the present modification, since the substrate contact 15 is positioned in every pixel, it is preferable to reduce the influence of the substrate contacts 15 on the sensitivity. Thus, each substrate contact 15 is positioned diagonally as viewed from the center of the photodiode 12 so as to reduce the influence of the substrate contacts 15.

As shown in FIG. 3B, in the second pixel 20g and the third pixel 20b, each substrate contact 15 is located closer to the photodiode 12, and thus the divide 17a of the depletion layer 17 protrudes toward the diffusion layers 12a. Thus, not only electrons 19a generated at a great depth but also part of electrons 19 generated at an intermediate depth from incident light 18 reach a region near the photodiode 12, and contribute to an increase in sensitivity as an electrical signal, whereby the sensitivity is varied. Thus, even if the same amount of light 18 is incident on the first pixel 20r, the second pixel 20g, and the third pixel 20b, the sensitivity varies among these pixels. However, since each substrate contact is not positioned in the middle of the boundary line between the pixels, but at an end of the boundary line (a diagonal end of each pixel), the influence of the variation in sensitivity can be reduced.

Thus, when the light 18 is incident on an intermediate portion between the photodiode 12 and the substrate contact 15 through the first color filter 13r (the color filter for transmitting red light therethrough) in a back-illuminated solid state image sensor, electrons 19a are generated by photoelectric conversion at a great depth in the semiconductor substrate 11. If there is no substrate contact 15, a divide 17b of the depletion layer 17 is located as shown by dashed line in the figure, and no electron 19a is absorbed by the photodiode 12. However, if there are the substrate contacts 15, the divide 17a of the depletion layer 17 is located as shown by solid line in the figure, and the electrons 19a are absorbed by the photodiode 12. Thus, the sensitivity varies depending on whether the substrate contact 15 is provided near the photodiode 12 or not. Accordingly, the sensitivity decreases in the lower part of the pixel array portion 20 on which the light 18 is incident from above (when the pixel array portion 20 is viewed in plan), and the sensitivity increases in the upper part of the pixel array portion 20 on which the light 18 is incident from beneath. The resultant shading is such that the sensitivity increases upward in the pixel array portion 20 when viewed as a whole. This phenomenon becomes remarkable as the pixel cells are miniaturized. This is because the influence of a variation in sensitivity due to the substrate contacts 15 increases as the pixel cells are miniaturized.

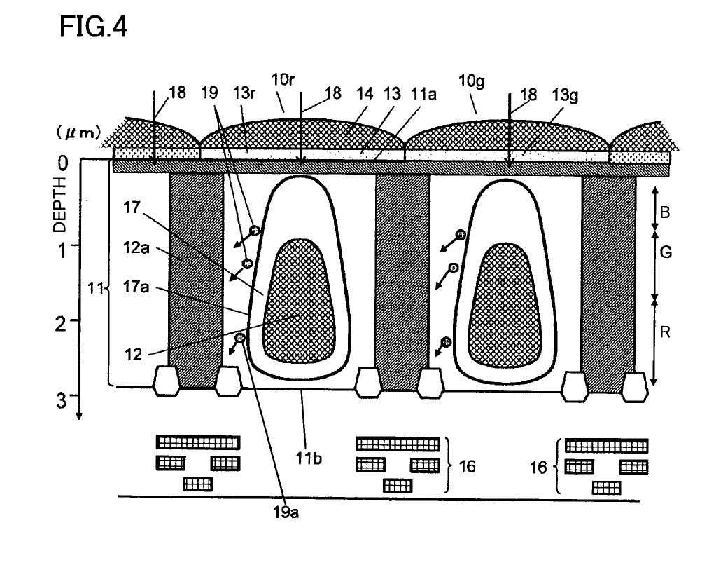

FIG. 4 is a cross-sectional view schematically showing the configuration of the solid state image sensor according to the embodiment of the present invention. FIG. 4A shows a cross section taken along line 4A-4A in FIG. 1A.

As shown in FIGS. 1A and 4, no substrate contact 15 is provided in the lower adjoining three pixels (the second pixel 10g, the first pixel 10r, and the second pixel 10g) in FIG. 1A. Accordingly, unlike the pixels shown in FIG. 1B or 3B, the divide 17a of the depletion layer 17 does not protrude toward the diffusion layers 12a at a great depth in the semiconductor substrate 11, when the light 18 is incident on the semiconductor substrate 11 through the microlens 14 and through the first color filter 13r or the second color filter 13g. Thus, as shown in FIG. 4, electrons 19, 19a generated from the light 18 reach the diffusion layers 12a without reaching the photodiode 12, and do not contribute to an increase in sensitivity as an electrical signal, whereby the sensitivity does not vary among the plurality of pixels.

An overview of the operation of the solid state image sensor of the present embodiment configured as described above will be described below.

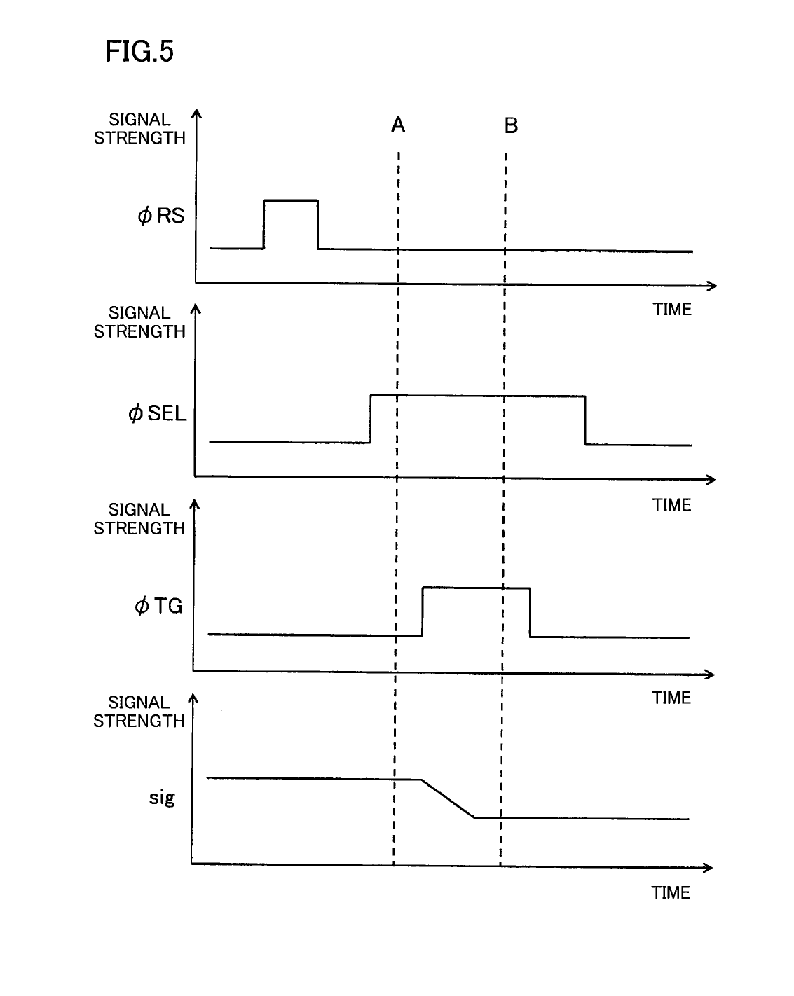

FIG. 5 is a timing chart illustrating an electrical operation of the solid state image sensor of the embodiment of the present invention. Note that since a circuit configuration described below is the same as that shown in FIG. 9B, some members such as transistors are described with the same reference characters as those in FIG. 9B for convenience.

First, as shown in the timing chart of FIG. 5, a high level select control pulse signal φRS for turning on reset transistors 210 is applied to a gate electrode of a reset transistor 210 of a pixel on a selected horizontal line. Then, a control pulse signal φSEL for turning off the reset transistors 210 and turning on select transistors 211 is applied to a gate electrode of a select transistor 211. At this time, a potential on a signal lines sig is held in the read circuit.

Then, a high level select control pulse signal φTG is applied to a gate electrode of a transfer transistor 208, and charges accumulated by photoelectric conversion are transferred from a photodiode 12 to a gate portion of an amplifying transistor 209. The charges transferred to the gate portion of the amplifying transistor 209 are converted to voltage information by parasitic capacitance, and the voltage information is transferred to the signal line sig via the amplifying transistor 209 and the select transistor 211. The read circuit outputs, as a signal, the difference between the level on the signal line sig, which is obtained at this time, and the level on the signal line sig, which has been held in the read circuit.

A manufacturing method of the solid state image sensor of the present embodiment will be described below.

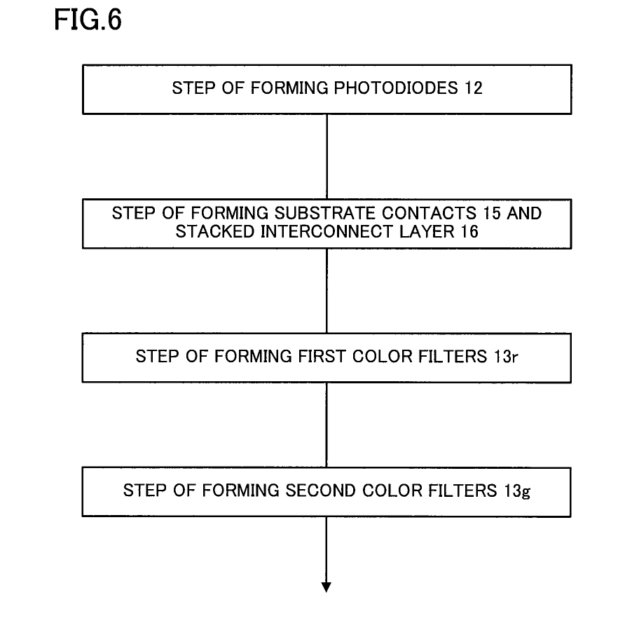

FIG. 6 is a flowchart illustrating the manufacturing method of the solid state image sensor of the present embodiment.

As shown in FIG. 6, the manufacturing method of the solid state image sensor of the present embodiment includes the steps of forming photodiodes 12, forming substrate contacts 15 and a stacked interconnect layer 16, forming first color filters 13r, and forming second color filters 13g. In the solid state image sensor of the present embodiment, the first color filters 13r selectively transmit first light therethrough, and the second color filters 13g selectively transmit second light therethrough. The second light has a shorter wavelength than that of the first light. The substrate contacts 15 are not formed in the first pixels 10r, but in the second pixels 10g.

Note that third color filters 13b for selectively transmit third light therethrough may further be formed. The third light has a shorter wavelength than those of the first light and the second light. In this case, it is preferable that the substrate contacts 15 not be formed in the first pixels 10r, but be formed either over the boundaries between the second pixel 10g and the third pixel 10b, or only in the third pixels 10b. Note that, for example, the first light is red light, the second light is green light, and the third light is blue light.

In the manufacturing method of the solid state image sensor of the present embodiment, the photodiodes 12 are formed by, e.g., introducing p-type impurities into the upper part of an n-type semiconductor substrate 11 by ion implantation or the like. For example, diffusion layers 12a containing a high concentration of n-type impurities are formed between adjoining ones of the photodiodes 12 in the semiconductor substrate 11.

Then, an interlayer insulating film is formed on a second main surface 11b of the semiconductor substrate 11, and the substrate contacts 15 are formed by a known method so as to extend through the interlayer insulating film and to contact the diffusion layers 12a. The substrate contacts 15 are made of, e.g., a metal such as copper or tungsten. Then, the stacked interconnect layer 16, in which metal interconnects such as copper or aluminum are provided, is formed on the second surface side of the semiconductor substrate 11 by a known method.

Then, the first color filters 13r and the second color filters 13g are formed on the first main surface of the semiconductor substrate 11. The third color filters 13b are also formed in the case of forming the third pixels 10b. Note that the filters of any color may be formed first. Then, microlenses 14 are formed in each pixel.

The solid state image sensor of the present embodiment can be formed by this method. The solid state image sensor produced by this method can prevent or reduce deformation of depletion layers 17 due to the presence of the substrate contacts 15, and can reduce a variation in sensitivity to long wavelength visible light among the pixels. Thus, generation of shading can be effectively reduced, whereby the sensitivity to long wavelength visible light can be made more uniform among the pixels.

(Modification of Solid State Image Sensor)

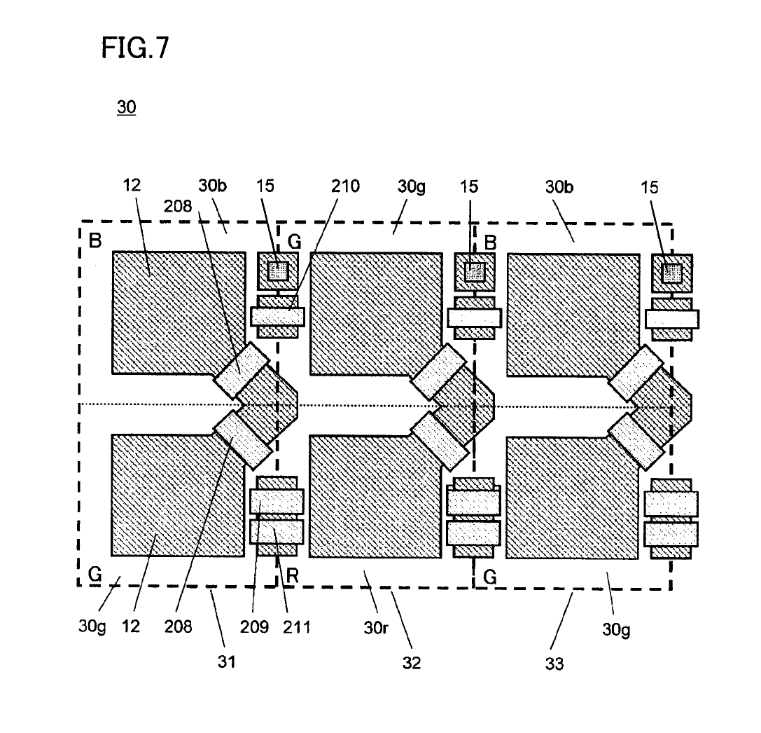

FIG. 7 is a plan view schematically showing the configuration of a pixel array portion 30 according to a modification of the solid state image sensor of FIGS. 1A-1B. Unlike the pixel array portion 10 of FIGS. 1A-1B, unit cells 31, 32, and 33, each including two photodiodes, are arranged in an array in the pixel array portion 30, and the two photodiodes are positioned so as to adjoin each other vertically in the figure. The configuration of the pixel array portion 30 is otherwise similar to that of the pixel array portion 10. Note that, in order to clearly show that the adjoining two photodiodes are connected together, FIG. 7 shows a plan view as viewed from a layer of interconnects for this connection.

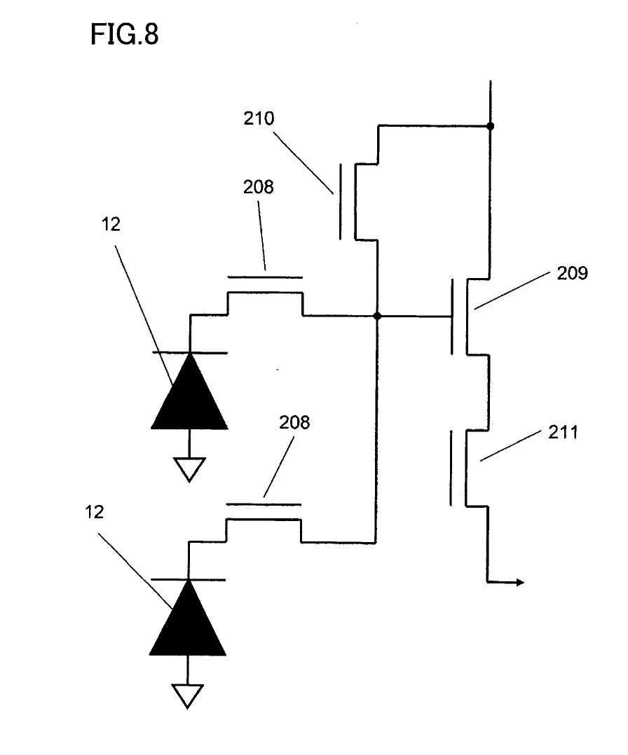

FIG. 8 is a schematic structural diagram showing a circuit block of the solid state image sensor of the present modification, and showing the circuit configuration of the unit cell 31, 32, 33 of the pixel array portion 30.

As shown in FIGS. 7-8, each of the unit cells 31, 32, and 33 may include two pixels.

Like the solid state image sensor of the above embodiment, the solid state image sensor of the present modification includes, as a basic configuration, first pixels 30r, second pixels 30g, and third pixels 30b as pixel cells. The first pixels 30r detect red light, the second pixels 30g detect green light, and the third pixels 30b detect blue light.

As in the solid state image sensor of the embodiment shown in FIG. 1B, each of the first pixel 30r, the second pixel 30g, and the third pixel 30b has a photodiode 12, a color filter 13, a microlens 14, and a circuit portion (not shown). In the example of FIG. 7, the unit cell 31 includes the second pixel 30g and the third pixel 30b, the unit cell 32 includes the first pixel 30r and the second pixel 30g, and the unit cell 33 includes the second pixel 30g and the third pixel 30b.

As shown in FIG. 8, the unit cell 31, for example, has two photodiodes 12 and five transistors in the circuit configuration. The five transistors are two transfer transistors 208, an amplifying transistor 209, a reset transistor 210, and a select transistor 211. Of the five transistors, the amplifying transistor 209, the reset transistor 210, and the select transistor 211 are shared to process signals detected by the two photodiodes 12.

Substrate contacts 15 for stabilizing a well potential are provided between laterally (horizontally) adjoining photodiodes 12 in the regions other than the first pixels 30r. In this example, the substrate contacts 15 are formed between adjoining ones of the upper three pixels (the third pixel 30b, the second pixel 30g, and the third pixel 30b). A reference voltage of, e.g., 0 V is applied to the substrate contacts 15.

The pixel array portion 30 configured as described above will be described below.

If the substrate contacts 15 are provided near the transfer transistors 208 in the pixel array portion 30, sensitivity increases according to the same principles as those described in the embodiment of FIGS. 1A-1B. Thus, the sensitivity varies between the two photodiodes 12 of the same unit cell 31, 32, 33. In particular, the regions near the transfer transistors 208 are susceptible to an N-type implantation layer, because the N-type implantation layer extends under the gate electrode of each transfer transistor 208 in order to increase transfer efficiency. Note that this implantation is performed when forming the photodiodes 12. Thus, providing another element, e.g., the reset transistor 210, between the transfer transistor 208 and the substrate contact 15 can reduce the variation in sensitivity between the two photodiodes 12.

Thus, the solid state image sensor having the pixel array portion 30 shown in FIG. 7 can further reduce the size, increase the integration level, and reduce the cost.

Note that although the pixel array portion 30 having a so-called 2-pixel, 1-unit cell configuration (two photodiodes are formed in a unit cell) is described above as an example, the present invention is not limited to this. For example, other configurations in which a unit cell is formed by a larger number of pixels, such as a 4-pixel, 1-unti cell configuration and a 6-cell, 1-unit cell configuration, may be used in the present invention.

In the solid state image sensors of the above embodiment and the modifications thereof, the plurality of pixels 10r, 10g, 10b and 30r, 30g, 30b in the pixel array portions 10 and 30 are arranged in a matrix pattern. However, the present invention is not limited to such an arrangement. For example, the pixel array portion may be formed by a plurality of pixels arranged in a honeycomb pattern.

The solid state image sensors of the above embodiment and the modifications thereof use primary color filters as the color filters. However, the primary color filters may be combined with complementary color filters or other filters. Alternatively, the first pixels in which no substrate contact 15 is provided may be pixels capable of detecting not only red light but also infrared light.

The configurations of the solid state image sensors of the above embodiment and the modifications thereof may be simplified. For example, substrate contacts may be provided between every adjoining ones of the photodiodes, and positioned closer to the photodiodes located under the color filters for transmitting light of a shorter wavelength therethrough. The advantages of the present invention can be sufficiently obtained even by this configuration.

The solid state image sensors of the above embodiment and the modifications thereof are shown by way of example only, and the shape, size, material, and the like of the members and regions may be varied without departing from the scope of the present invention. For example, the planar shape of the photodiodes 12 is not limited to the quadrilateral, and the arrangement of the color filters is not limited to the Bayer pattern or the like.

The solid state image sensor described above as an example of the present invention is capable of reducing or preventing deformation of the depletion layers due to the presence of the substrate contacts, thereby reducing a variation in sensitivity to long wavelength incident light among the pixels. Thus, generation of shading can be reduced. Since the sensitivity to long wavelength incident light can be made more uniform among the plurality of pixels, a high image-quality solid state image sensor, which can be used as imaging devices such as a digital still camera, can be implemented.

What is claimed is:

1. A solid state image sensor, comprising:
a semiconductor substrate having a first main surface and a second main surface which face each other;
a first pixel and a second pixel, each including a light receiving portion formed in the semiconductor substrate and configured to perform photoelectric conversion;
a first color filter formed in an upper part of the first pixel on the first main surface side of the semiconductor substrate;
a second color filter formed in an upper part of the second pixel on the first main surface side of the semiconductor substrate;
a metal interconnect layer formed on the second main surface side of the semiconductor substrate; and
a substrate contact connected to the second main surface of the semiconductor substrate, and provided between the metal interconnect layer and the second main surface, wherein
the first color filter mainly transmits first light therethrough, and the second color filter mainly transmits second light therethrough,
the second light has a shorter wavelength than that of the first light, and
the substrate contact is not provided in the first pixel.

2. The solid state image sensor of claim 1, further comprising:
a third pixel including the light receiving portion formed in the semiconductor substrate; and
a third color filter formed in an upper part of the third pixel on the first main surface side of the semiconductor substrate, wherein
the third color filter mainly transmits third light therethrough,
the third light has a shorter wavelength than that of the second light, and
the substrate contact is provided at least in the third pixel.

3. The solid state image sensor of claim 2, wherein
the second pixel and the third pixel are positioned so as to adjoin each other, and
the substrate contact is formed over a boundary between the second pixel and the third pixel.

4. The solid state image sensor of claim 3, wherein
the substrate contact is formed between the light receiving portion of the second pixel and the light receiving portion of the third pixel as viewed in plan.

5. The solid state image sensor of claim 4, wherein
the substrate contact is formed at a position closer to the light receiving portion of the third pixel than to the light receiving portion of the second pixel as viewed in plan.

6. The solid state image sensor of claim 2, wherein
the first light is red light, the second light is green light, and the third light is blue light, and
multiple ones of the first pixel, the second pixel, and the third pixel are provided, and are arranged in a Bayer pattern.

7. The solid state image sensor of claim 2, further comprising:
a transfer transistor provided on the first main surface of the semiconductor substrate, and configured to transfer a signal accumulated in the first pixel, the second pixel, or the third pixel; and
a reset transistor provided on the first main surface of the semiconductor substrate, wherein
the reset transistor is positioned between the transfer transistor and the substrate contact as viewed in plan.

8. A solid state image sensor, comprising:
a semiconductor substrate having a first main surface and a second main surface, which face each other;
a first pixel and a second pixel, each including a light receiving portion formed in the semiconductor substrate and configured to perform photoelectric conversion;
a first color filter formed in an upper part of the first pixel on the first main surface side of the semiconductor substrate;
a second color filter formed in an upper part of the second pixel on the first main surface side of the semiconductor substrate;
a metal interconnect layer formed on the second main surface side of the semiconductor substrate; and
a substrate contact connected to the second main surface of the semiconductor substrate, and provided between the metal interconnect layer and the second main surface, wherein
the first color filter mainly transmits first light therethrough, and the second color filter mainly transmits second light therethrough,
the second light has a shorter wavelength than that of the first light, and
the substrate contact is provided in each of the first pixel and the second pixel so as to be positioned diagonally as viewed from a center of the light receiving portion of each of the first pixel and the second pixel.

9. A method for manufacturing a solid state image sensor, comprising the steps of:
forming a light receiving portion, which is configured to convert light incident from a first main surface side of a semiconductor substrate to a signal, in each of a first pixel and a second pixel in the semiconductor substrate;
forming a substrate contact connected to a second main surface of the semiconductor substrate, and a metal interconnect layer, on the second main surface side of the semiconductor substrate;
forming a first color filter in an upper part of the first pixel on the first main surface side of the semiconductor substrate; and
forming a second color filter in an upper part of the second pixel on the first main surface side of the semiconductor substrate, wherein
the first color filter mainly transmits first light therethrough, and the second color filter mainly transmits second light therethrough,
the second light has a shorter wavelength than that of the first light, and
the substrate contact is not formed in the first pixel.

10. The method of claim 9, wherein
the light receiving portion is formed also in a third pixel in the step of forming the light receiving portion, the method further comprising the step of:
forming, in an upper part of the third pixel, a third color filter configured to mainly transfer therethrough third light having a shorter wavelength than that of the second light, wherein
the substrate contact is formed at least in the third pixel in the step of forming the substrate contact.
